(19) United States
(12) Patent Application Publication
(10) Pub. No.: US 2009/0014867 A1
(43) Pub. Date: Jan. 15, 2009

(54) SEAL RING FOR GLASS WALL MICROELECTRONICS PACKAGE

(76) Inventor: Casey Krawiec, La Jolla, CA (US)

Correspondence Address: PROCOPIO, CORY, HARGREAVES & SAVITCH LLP, 530 B STREET, SUITE 2100, SAN DIEGO, CA, 92101, US

(21) Appl. No.: 11/775,735

(22) Filed: Jul. 10, 2007

(51) Int. Cl. H01L 23/10

(52) U.S. Cl. 257/728; 257/E23.193

(57) ABSTRACT

A seal ring formed from a conductive material has at least one recessed area formed on an internal or external surface which is dimensioned to permit attachment of a wire bond so that the wire and any attachment material remain recessed from the upper and lower contact surfaces of the seal ring, allowing the seal ring to make flat and even contact with the adjacent package layer so that a hermetic seal is formed.

### FIELD OF THE INVENTION

The present invention relates to microelectronics packages for high frequency/high speed devices, and more specifically to a seal ring for hermetically-sealed glass wall packages.

### BACKGROUND OF THE INVENTION

State of the art technologies such as mobile telephones, laptop and notebook computers, and hand-held communication devices, among others, have been improved and made more user-friendly in terms of weight and cost reductions by advances in microelectronic circuit design and materials that provide faster computing speeds with lower power demands. Product performance requirements spiral from the effects of increasing operating speed, decreasing package size, lowering cost, and reducing time to market. These spiraling requirements raise new component packaging and handling issues in which the circuit advances must be complemented by circuit packaging to take full advantage of the technology improvements. Packaging must protect the chip against adverse environmental conditions and dissipate the tremendous amount of heat produced, yet maintaining the electrical integrity.

A variety of packages are available, and requirements vary according to the frequency of the device being packaged. Conventional transfer molded plastic packages can be used for handset applications through 1-2 GHz and as high as 10-12 GHz for other applications where electrical performance can tolerate the losses because of the plastic. Low-cost hermetic glass wall packages that can handle the thermal requirements that plastic does not are available for amplifiers through about 12 GHz. Ceramic packages designed for both low- and high-power devices are available for applications up to and above 50 GHz.

Microwave systems used in high speed communication devices present unique demands on packaging as a result of the relatively short wavelength of the signal, the functions performed by the systems, and the types of devices used. High speed microelectronic packages, e.g., Monolithic Microwave Integrated Circuits (MMICs) are typically made from compound semiconductors such as gallium-arsenide (GaAs), silicon-germanium (SiGe), or indium-phosphide (InP). MMIC performance tends to degrade rapidly in the presence of moisture. Degradation can be observed through measurement of signal attenuation, RF loss, and parameter shift. In particular, condensation is a major concern if it occurs on the surface of the MMICs—it can lower device surface temperature and result in conductive dendrite formations that can bridge insulation within just a few days. Thus, hermeticity of the MMIC packages is crucial to avoid degradation and losses.

It is also well known that choice of dielectric materials is critical in controlling signal losses in high frequency applications, and MMICs are frequently packaged using ceramic or glass wall packages. Such packages are formed in a layered structure including a conductive base and one or more layers of dielectric material forming a seal ring that surrounds the MMIC, and a lid or cap that is bonded to the top of the seal ring to form a hermetic seal, providing both hermeticity and low signal losses. Examples of packages of this general structure are described in U.S. Pat. No. 6,172,412 and No. 5,753,972, which are incorporated herein by reference.

In some applications, the seal ring and/or lid will be metal. Package technologies with seal rings include, but are not limited to, packages made from co-fired ceramic (both high- and low-temperature (HTCC and LTCC)), post-fired ceramic, and glass wall technology. Unless the seal ring and lid are grounded, they will be electrically separate and float. Electric fields, especially those generated by high frequency and high speed digital signals within the package, tend to couple with these metal components causing resonance that disrupts the digital signals. The seal rings on co-fired ceramics and post-fired ceramic packages can be grounded by including metal-filled vias that are built into the ceramic for connecting the seal ring to the ground. Alternatively, printed metallization on the edges of the ceramic can be used to connect the seal rings to ground. One technique used for ground the seal rings on glass walled packages is to solder a strap or wire from the base to the seal ring. The grounding wirebonds can be placed on the seal ring during assembly of the package, when the microchip, substrates and other components are being loaded into the package.

To provide an example of one of the above-described packages, glass wall packages can have seal rings formed from an alloy such as Kovar® (ASTM F-15), which is selected, in part, because its coefficient of thermal expansion closely matches that of the glass. After placement of the microchip(s) within the package, a metal lid is soldered to the top of the seal ring. To prevent floating, a ground wire is wirebonded to the seal ring and to the base or ground pad prior to attachment of the lid. While this is generally successful from an electrical perspective, it may interfere with creation of a proper hermetic seal, making the package design unacceptable from a mechanical, and ultimately, electronic, perspective. Accordingly, the need remains for a package that can be readily assembled and is capable of reliably producing a hermetic seal and providing the desired electrical performance.

### BRIEF SUMMARY OF THE INVENTION

It is an advantage of the present invention to provide a seal ring for use with glass wall packages that facilitates wirebonding without interfering with the formation of a hermetic seal.

In an exemplary embodiment, a seal ring comprising a conductive material has at least one recessed area, e.g., a notch or ledge, formed on an internal or external surface which is dimensioned to permit attachment of a wire bond so that the wire and any attachment material remain recessed from the upper and lower contact surfaces of the seal ring, allowing the seal ring to make flat and even contact with the adjacent package layer so that a hermetic seal is formed.

The at least one recessed area is formed during or after formation of the seal ring by chemical etching or stamping, or by other manufacturing methods as are known in the art. In the exemplary embodiment, a recessed area is formed on each of four sides of the seal ring to give the choice of selecting the most convenient recess for attaching the wire.

Any of the three standard methods of wire bonding may be used to attach the ground wire to the seal ring and base plate. Thermocompression or thermosonic methods may be used and form a ball wirebond, or ultrasonic or thermosonic methods may be used and form a wedge wirebond. All three standard methods are well known in the art and any of these methods may be used. The bonding wire is typically gold. In some cases, aluminum or copper may also be used.

### BRIEF DESCRIPTION OF THE DRAWINGS

The present invention will be more clearly understood from the following detailed description of the preferred embodiments of the invention and from the attached drawings, in which:

FIG. 1 is an exploded perspective view of a glass wall package.

FIG. 2 is a cross sectional view of the inventive seal ring taken along line A-A of FIG. 1.

FIG. 3 is a perspective view of the detail of an exemplary notch in the inventive seal ring.

FIG. 4 is a diagrammatic cross-sectional view of a glass wall package incorporating the inventive seal ring showing a wirebond attachment to the conductive base.

FIG. 5 is a diagrammatic top view of an alternate embodiment of the seal ring.

### DETAILED DESCRIPTION OF THE PREFERRED EMBODIMENTS

The following detailed description is directed to an exemplary application of the inventive seal ring as used in a glass wall package. It will be recognized by those in the art that the inventive seal ring may be incorporated in other types of high frequency microelectronic packages, including ceramic or metal where reliable grounding of the seal ring and/or lid is desired.

The components of an exemplary glass wall package, shown in FIG. 1, include a base 600, which can be either metal or ceramic with a conductive upper surface, a lower glass form 500, a lead frame 400, an upper glass form 300, a seal ring 200 with notches 210, and a lid 100, which can be either a metal alloy, ceramic, or in some applications, plastic. The upper glass form 500 and the lower glass form 300 may be made of a glass paste which is then cured at a lower temperature to drive off solvents.

In the exemplary embodiment, the upper and lower glass forms are made from Corning 7052 (alkali barium borosilicate) glass or an equivalent glass, plus 15-25 percent alumina powder. Selection of the equivalent glass and other acceptable materials will be readily apparent to those in the art. Seal ring 200 is formed from a conductive material, typically a metal alloy. In the preferred embodiment, ASTM F-15 alloy (Kovar®) is used. ASTM F-15, which is an alloy consisting of 53.7% iron, 29% nickel, 17% cobalt, 0.2% silicon, 0.05% manganese, and 0.06% carbon, is commercially available from numerous sources. Other alloys may be used and will preferably be selected to match the coefficient of thermal expansion of the dielectric material of the package. After the MMICs or other microelectronic device(s) are placed in the package and the wire bonds are completed, the metal lid is attached to the seal ring using solder to create a hermetic seal.

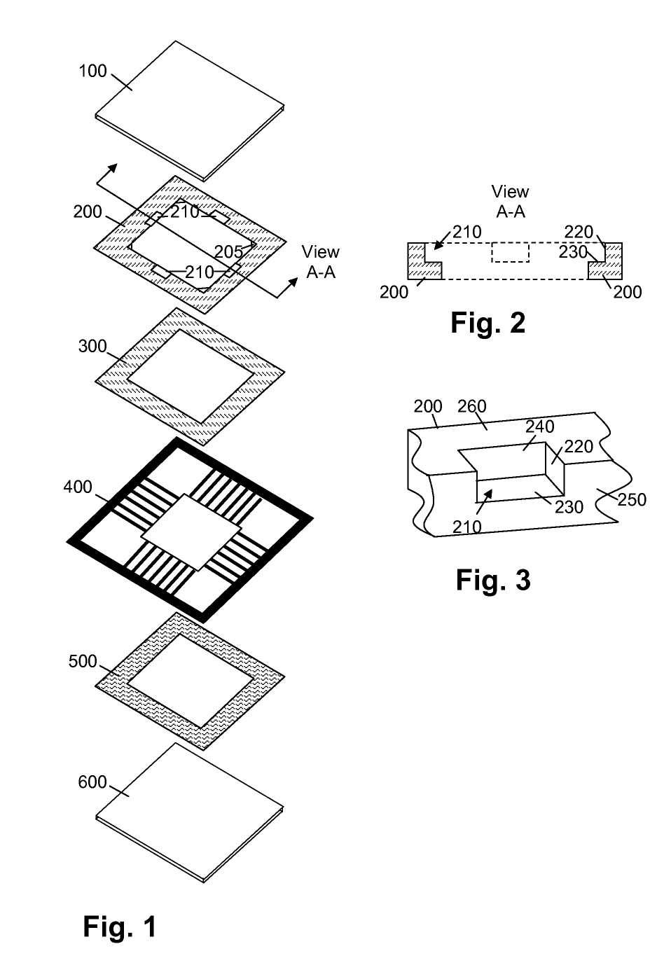

For establishing a hermetic seal with the seal ring 200 and the lid 100, it is important that the seal ring is planar with a uniform thickness. As shown in FIGS. 1 through 4, seal ring 200 has one or more recesses 210 (notches, ledges, or steps) that cut into the edge formed by the intersection of upper surface 260 and inner wall 250 of seal ring 200. As illustrated in FIGS. 2 and 3, recess 210 extends approximately a quarter the width of the sidewall and half the thickness of the seal ring, however, the dimensions may vary to create a sufficient gap to permit unobstructed formation of the wirebond while ensuring the integrity of the seal ring. While the recesses 210 are shown located at the middle of each side, they need not be centered on each side, and can be shifted towards the corners. In an alternate embodiment, the wirebond may be located on the exterior of the package by forming recess(es) in the edge defined by the outer surface and upper surface 260. In one implementation shown in FIG. 5, the recesses 810 formed in seal ring 800 by partially cutting into the corners of the seal ring at a depth of about half the thickness of the seal ring.

Seal rings are formed using either chemical etching processes or by mechanical stamping. Both manufacturing methods are standard and well known in the industry. If chemical etching is used, standard photolithography techniques using photoresist to form the pattern of the seal ring on the metal alloy are employed, followed by wet etching of the metal alloy to remove the unprotected material, leaving the seal ring. A separate masking operation is used in which the seal ring is protected with photoresist, with windows being opened in the photoresist where the recesses are to be formed by the etching operation. Alternatively, the order of the steps can be reversed, with the recesses being formed first.

If mechanical stamping is used, the seal ring can be formed in one or two stamping steps depending on the stamping die used. As another manufacturing option, a combination of stamping and etching may be used to create the seal ring of the present invention.

Referring to FIG. 3, recesses are dimensioned as needed for the particular application, depending on vertical and horizontal thicknesses of the seal ring and the thickness or diameter of the conductor to be used for the ground connection.

In the exemplary embodiment, the depth of recess 210 is approximately one-half the thickness of the seal ring. A typical depth (from upper surface 260 to horizontal ledge 230) is on the order of 0.125 mm (0.005 in.) for a seal ring thickness of 0.25 mm (0.010 in.). The length of recess 200, between vertical side walls 220, is on the order of 0.5 mm (0.020 in.), and the width, from inner wall 250 to vertical back wall 240, is on the order of 0.25 mm (0.010 in.), which represents about one-quarter of the width of the seal ring sidewall. The inner corners of the recess will preferably be rounded to avoid creation of a stress point on the seal ring and also due to the nature of the chemical etch process.

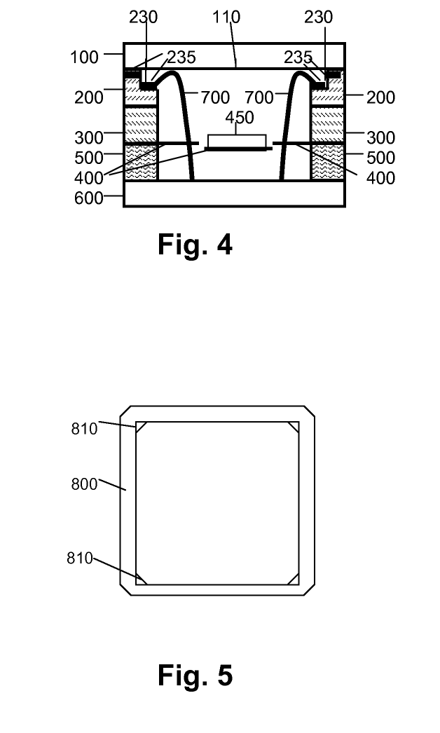

After formation, the seal ring used in a glass wall package is cleaned and outgassed, then heated in air to oxidize its surface. The seal ring 200, glass forms 300 and 500, lead frame 400 and base 600 are assembled using a glass melting/sealing process. The seal ring is cleaned of any residual oxide and electroplated first with nickel for adhesion and hardness properties, and then with gold. The nickel/gold finish 235 (shown in FIG. 4) provides good corrosion resistance and is readily wire bondable using gold wire. The finish plating 235 should be compatible with the type of wire, e.g., gold, copper or aluminum, that will be employed for connection of the MMIC.

FIG. 4 illustrates an exemplary package assembly showing wires 700 bonded to recesses 230 for connection to base 600 for grounding. Typically, only one wire will be used to provide the ground connection, and the most convenient one of multiple recesses will be selected for ease of connection to base 600.

The inventive seal ring technology can be used with ceramic or metal packages that are used in high frequency applications where good grounding of the seal ring and lid is desired for electrical performance. The seal ring of the present invention may be used on other types of packages and is not limited to packages incorporating lead frames.

The foregoing description of preferred embodiments is not intended to be limited to specific details disclosed herein. Rather, the present invention extends to all functionally equivalent structures, methods and uses as may fall within the scope of the appended claims.

1. A seal ring for a hermetically sealed microelectronic package, comprising:
a conductive planar ring having a ring thickness, an inner surface, an outer surface and a ring width between the inner surface and the outer surface, wherein at least one recess is formed in one of the inner surface and the outer surface, the recess having dimensions of less than the ring thickness and less than the ring width to define a step adapted for attachment of a wirebond; and
a finish plating disposed on the step, the finish plating comprising a conductive metal.

2. The seal ring of claim 1, wherein the at least one recess has a depth of approximately one-half the ring thickness.

3. The seal ring of claim 1, wherein the ring has four sides and the at least one recess comprises four recesses, with one recess disposed on each of the four sides.

4. The seal ring of claim 3, wherein the one recess is disposed in a middle of each side.

5. The seal ring of claim 3, wherein the recesses are disposed on corners between the four sides.

6. The seal ring of claim 1, wherein the package is glass wall and the seal ring is formed of ASTM F-15 alloy.

7. The seal ring of claim 1, wherein the finish plating is gold.

8. A seal ring for a hermetically sealed microelectronic package having a grounded base, the seal ring comprising:
a conductive planar ring having a uniform ring thickness and four sides, each having an inner side, an outer side, with a ring width between the inner side and the outer side wherein at least one recess is formed in the inner side, the recess having dimensions of less than the ring thickness and less than the ring width to define a step adapted for attachment of a wirebond for connecting the seal ring to the grounded base.

9. The seal ring of claim 8, wherein the at least one recess has a depth of approximately one-half the ring thickness.

10. The seal ring of claim 8, wherein the at least one recess comprises four recesses, with one recess disposed on each of the four sides.

11. The seal ring of claim 10, wherein the one recess is disposed in a middle of each side.

12. The seal ring of claim 8, wherein the recesses are disposed at corners between the four sides.

13. The seal ring of claim 8, wherein the package is glass wall and the seal ring is formed of ASTM F-15 alloy.

14. The seal ring of claim 8, further comprising a finish plating disposed on the step, the finish plating comprising a conductive metal that is compatible with the wirebond.

15. The seal ring of claim 14, wherein the finish plating is gold.
